(19) United States
(12) Patent Application Publication
(10) Pub. No.: US 2007/0218588 A1
(43) Pub. Date: Sep. 20, 2007

(54) INTEGRATED CIRCUIT PACKAGE HAVING STACKED INTEGRATED CIRCUITS AND METHOD THEREFOR

(75) Inventors: Hem P. Takiar, Fremont, CA (US); Shrikar Bhagath, San Jose, CA (US); Ken Jian Ming Wang, San Francisco, CA (US)

Correspondence Address: BEYER WEAVER LLP/ SANDISK, P.O. BOX 70250, OAKLAND, CA, 94612-0250, US

(73) Assignee: SanDisk Corporation

(21) Appl. No.: 11/750,768

(22) Filed: May 18, 2007

Related U.S. Application Data
(62) Division of application No. 11/140,608, filed on May 26, 2005.

(51) Int. Cl. H01L 21/00

(52) U.S. Cl. 438/109; 257/E21.001

(57) ABSTRACT

Improved techniques for stacking integrated circuit dies within an integrated circuit package are disclosed. These improved techniques allow greater stacking density of integrated circuit dies within an integrated circuit package. Additionally, the improved stacking techniques permit conventional bonding techniques for electrical connection of the various integrated circuit dies to each other or to a substrate. These improved approaches are particularly useful for stacking same size (and often same function) integrated circuit dies within integrated circuit packages. One example of such an integrated circuit package is a non-volatile memory integrated circuit package that contains multiple, like-sized memory storage integrated circuit dies arranged in a stack.

### CROSS-REFERENCE TO RELATED APPLICATIONS

This application is a divisional of U.S. application Ser. No. 11/140,608 (Attorney Docket No.: SDK1P027/SDK0614), filed May 26, 2005, and entitled “INTEGRATED CIRCUIT PACKAGE HAVING STACKED INTEGRATED CIRCUITS AND METHOD THEREFOR,” which is related to U.S. patent application Ser. No. 10/463,742 (Attorney Docket. No.: SDK1P016/446), filed Jun. 16, 2003, and entitled “INTEGRATED CIRCUIT PACKAGE HAVING STACKED INTEGRATED CIRCUITS AND METHOD THEREFOR”, and which is hereby incorporated by reference herein. This application is also related to U.S. patent application Ser. No. 10/463,051 (Attorney Docket No.: SDK1P013/369), filed Jun. 16, 2003, and entitled “STACKABLE INTEGRATED CIRCUIT PACKAGE AND METHOD THEREFOR”, and which is hereby incorporated by reference herein.

### BACKGROUND OF THE INVENTION

1. Field of the Invention

The present invention relates to integrated circuit packages and, more particularly, to integrated circuit packages that include stacked integrated circuits.

2. Description of the Related Art

As the trend for memory integrated circuit (IC) packages to be smaller and their memory density to be larger continues, advancements in packaging integrated circuits are needed. One recent advancement involves stacking multiple integrated circuit dies within a single IC package. In one approach, such stacking involves stacking a smaller die on a larger die. Each of the dies is wire bonded to a substrate. The use of wire bonding necessarily requires that access to bonding pads of each of the dies be available; consequently, the upper die, when stacked on the lower die, must be small so as to not inhibit access to the bonding pads of the lower die. This type of stacking has, for example, been used with same function dies (e.g., two Flash memory dies) or different function dies (e.g., one Flash memory die and one SRAM die). Stacking of two or three dies has been done for stacked Chip Scale Packages (stacked CSP) and stacked Thin Small Outline Packages (TSOP). In another approach, like-sized dies can be stacked by placing a spacer, namely a relatively thick insulator, between the dies. Although the spacer provides the lower die with sufficient space so that it can be wire bonded, the spacer disadvantageously makes the integrated circuit package thicker or limits the number of dies that can fit within the integrated circuit package of a given size.

FIG. 1 is a cross-sectional view of a conventional integrated circuit package 100 having a stack of integrated circuit dies. The integrated circuit package 100 includes a substrate 102. A pair of integrated circuit dies 104 and 106 are stacked on the substrate 102 but are separated by a spacer die 108. The spacer die 108 typically has a similar thickness as do the integrated circuit dies 104 and 106. However, the width of the spacer die 108 is typically smaller than the width of the integrated circuit dies 104 and 106 so that the bond pads of the lower integrated circuit die 104 can be wire bonded via wires 110 to the substrate 102. The upper integrated circuit die 106 can also be wire bonded via wires 112 to the substrate 102. Hence, by providing the spacer die 108 between the integrated circuit dies 104 and 106, the integrated circuit package 100 is able to include a plurality of like-size integrated circuit dies. Unfortunately, however, the spacer die 108 increases the overall height of the integrated circuit package 100. As a result, when the overall height of an integrated circuit package is constrained, the presence of spacer dies to facilitate stacking of integrated circuit chips operates to limit the number of integrated circuit dies that can be provided within the integrated circuit package.

Accordingly, there remains a need to provide improved techniques to stack integrated circuit dies within an integrated circuit package.

### SUMMARY OF THE INVENTION

Broadly speaking, the invention provides improved techniques for stacking integrated circuit dies within an integrated circuit package. These improved techniques allow greater stacking density of integrated circuit dies within an integrated circuit package. Additionally, the improved stacking techniques permit conventional bonding techniques for electrical connection of the various integrated circuit dies to each other or to a substrate. Still further, the improved stacking techniques substantially reduce the number of process steps required to fabricate integrated circuit packages having a plurality of stacked integrated circuit dies.

The invention can be implemented in numerous ways, including as a system, apparatus, device or method. Several embodiments of the invention are discussed below.

As an integrated circuit package, one embodiment of the invention includes at least: an offset stack of integrated circuit dies without having spacer dies between each of the integrated circuit dies in the offset stack; and a substrate that supports the offset stack, the offset stack being coupled to the substrate.

As an integrated circuit package, another embodiment of the invention includes at least: a substrate having a plurality of substrate bonding areas; a first integrated circuit die having an active surface and a non-active surface, the non-active surface being attached to the substrate, the active surface of the first integrated circuit die having first bonding pads arranged on at least one but not more than two predetermined sides of the four sides of the active surface; first wire bonds provided between the first bonding pads and one or more of the substrate bonding areas; a first adhesive layer provided on at least a portion of the active surface of the first integrated circuit die; and a second integrated circuit die having an active surface and a non-active surface, the non-active surface of the second integrated circuit die being attached to the active surface of the first integrated circuit die by the first adhesive layer, and the active surface of the second integrated circuit die having second bonding pads arranged on at least one but not more than two predetermined sides of the four sides of the active surface. The second integrated circuit die is attached to the first integrated circuit die in an offset manner such that the second integrated circuit die is not attached over the first bonding pads of the first integrated circuit die.

As an integrated circuit package, another embodiment of the invention includes at least: a substrate having a plurality of substrate bonding areas; a first integrated circuit die having an active surface and a non-active surface, the non-active surface being attached to the substrate, the active surface of the first integrated circuit die having first bonding pads arranged on at least one but not more than two predetermined sides of the four sides of the active surface; first wire bonds provided between the first bonding pads and one or more of the substrate bonding areas; and a second integrated circuit die having an active surface and a non-active surface, the non-active surface of the second integrated circuit die being attached to the active surface of the first integrated circuit die, and the active surface of the second integrated circuit die having second bonding pads arranged on at least one but not more than two predetermined sides of the four sides of the active surface. The second integrated circuit die is attached to the first integrated circuit die in an offset manner such that the second integrated circuit die is not attached over the first bonding pads of the first integrated circuit die.

As a memory integrated circuit package, one embodiment of the invention includes at least: a substrate having a plurality of substrate bonding areas; a first memory die having an active surface and a non-active surface, the non-active surface being attached to the substrate, the active surface of the first memory die having first bonding pads arranged on at least one but not more than two predetermined sides of the four sides of the active surface; first wire bonds provided between the first bonding pads and one or more of the substrate bonding areas; a first adhesive layer provided on at least a portion of the active surface of the first memory die; a second memory die having an active surface and a non-active surface, the non-active surface of the second memory die being attached to the active surface of the first memory die by the first adhesive layer, and the active surface of the second memory die having second bonding pads arranged on at least one but not more than two predetermined sides of the four sides of the active surface, the second memory die being attached to the first memory die in an offset manner such that the second memory die is not attached over the first bonding pads of the first memory die; second wire bonds provided between the second bonding pads and one or more of the substrate bonding areas or the first bonding pads; a second adhesive layer provided on at least a portion of the active surface of the second memory die; a third memory die having an active surface and a non-active surface, the non-active surface of the third memory die being attached to the active surface of the second memory die by the second adhesive layer, and the active surface of the third memory die having second bonding pads arranged on at least one but not more than two predetermined sides of the four sides of the active surface, the third memory die being attached to the second memory die in an offset manner such that the third memory die is not attached over the second bonding pads of the second memory die; third wire bonds provided between the third bonding pads and one or more of the substrate bonding areas, the first bonding pads or the second bonding pads; a third adhesive layer provided on at least a portion of the active surface of the third memory die; and a fourth memory die having an active surface and a non-active surface, the non-active surface of the fourth memory die being attached to the active surface of the third memory die by the third adhesive layer, and the active surface of the fourth memory die having fourth bonding pads arranged on the active surface, the fourth memory die being attached to the third memory die in an offset manner such that the fourth memory die is not attached over the third bonding pads of the third memory die.

As a method for forming an integrated circuit package having a plurality of stacked integrated circuit dies, one embodiment of the invention includes the acts of: obtaining a substrate having a plurality of electrical bond areas; obtaining first, second, third and fourth integrated circuit dies having respective sets of bonding pads, the bonding pads of the first, second and third integrated circuit dies being limited to at least one but more than two sides thereof; arranging the first integrated circuit die with respect to the substrate; providing a first adhesive for use between the first and second integrated circuit dies; placing the second integrated circuit die on the first integrated circuit die in an offset manner with the first adhesive in between; providing a second adhesive for use between the second and third integrated circuit dies; placing the third integrated circuit die on the second integrated circuit die in an offset manner with the second adhesive in between; providing a third adhesive for use between the third and fourth integrated circuit dies; placing the fourth integrated circuit die on the third integrated circuit die in an offset manner with the third adhesive in between; concurrently curing the first adhesive, the second adhesive and the third adhesive; and subsequently wire bonding the bond pads of the first integrated circuit die, the second integrated circuit die, the third integrated circuit die and the fourth integrated circuit die to the electrical bond areas and/or each other.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1 is a cross-sectional view of a conventional integrated circuit package.

FIG. 2 is a cross-sectional view of an integrated circuit package according to one embodiment of the invention.

FIG. 3 is a cross-sectional view of an integrated circuit package according to another embodiment of the invention.

FIGS. 4A, 4B and 4C are diagrams illustrating a top view of an integrated circuit die in the context of a bond pad redistribution process. FIG. 5 is a cross-sectional view of an integrated circuit package according to another embodiment of the invention.

FIG. 6 is a cross-sectional view of an integrated circuit package according to another embodiment of the invention.

FIGS. 7A-7D are cross-sectional views of integrated circuit packages according to other embodiments of the invention.

FIGS. 8A and 8B are cross-sectional views of other integrated circuit packages having a stack of integrated circuits as well as at least one other integrated circuit separate from the stack.

FIGS. 9A and 9B are flow diagrams of package assembly processing according to one embodiment of the invention.

FIG. 10 is a flow diagram of a bond pad redistribution process according to one embodiment of the invention.

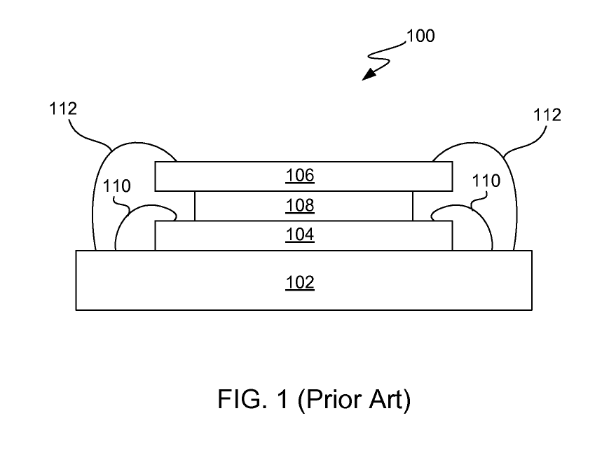

### DETAILED DESCRIPTION OF THE INVENTION

The invention provides improved techniques for stacking integrated circuit dies within an integrated circuit package. These improved techniques allow greater stacking density of integrated circuit dies within an integrated circuit package. Additionally, the improved stacking techniques permit conventional bonding techniques for electrical connection of the various integrated circuit dies to each other or to a substrate. Still further, the improved stacking techniques substantially reduce the number of process steps required to fabricate integrated circuit packages having a plurality of stacked integrated circuit dies.

These techniques are particularly useful for integrated circuit packages that are thin or low profile because the resulting integrated circuit packages can provided greater utility (i.e., greater functional ability or greater capacity). These improved approaches are also particularly useful for stacking same size (and often same function) integrated circuit chips with integrated circuit packages. One example of such an integrated circuit package is a non-volatile memory integrated circuit package that contains multiple, like-sized memory storage integrated circuit chips stacked of a substrate without the need for spacers.

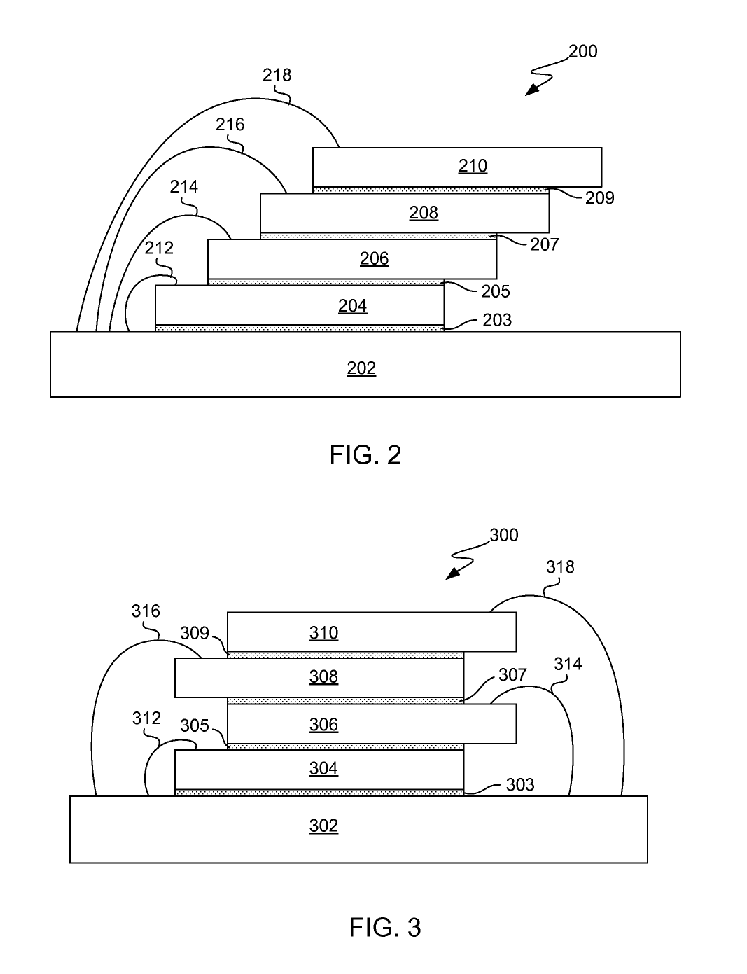

Embodiments of the invention are discussed below with reference to FIGS. 2-10. However, those skilled in the art will readily appreciate that the detailed description given herein with respect to these figures is for explanatory purposes as the invention extends beyond these limited embodiments.

FIG. 2 is a cross-sectional view of an integrated circuit package 200 according to one embodiment of the invention. The integrated circuit package 200 includes a substrate 202. The substrate 202 can vary depending upon implementation. For example, the substrate 202 can be a printed circuit board, a ceramic substrate, a lead frame, or a tape.

A plurality of integrated circuit dies are stacked on the substrate 202. Although not necessary, in this embodiment, all of the integrated circuit dies are the same size. The functions of the integrated circuit dies can all be the same or some or all can be different. More specifically, in this embodiment, a first integrated circuit die 204 is stacked on the substrate 202. The first integrated circuit die 204 can be held in place by an adhesive layer 203. A second integrated circuit die 206 is stacked on the first integrated circuit die 204. However, the second integrated circuit die 206 is not completely aligned over the first integrated circuit die 204. Instead, the second integrated circuit die 206 is stacked on the first integrated circuit die 204 in offset manner. As shown in FIG. 2, the second integrated circuit die 206 is offset to the right by a relatively small portion as compared to the overall width of the first integrated circuit die 204. The second integrated circuit die 206 can be held in place by an adhesive layer 205. Additionally, a third integrated circuit die 208 is stacked on the second integrated circuit die 206 in an offset manner. Here, the third integrated circuit die 208 is offset to the right with respect to the second integrated circuit die 206. The third integrated circuit die 208 can be held in place by an adhesive layer 207. Still further, a fourth integrated circuit die 210 is stacked on the third integrated circuit die 208 in an offset manner. The fourth integrated circuit die 210 is offset to the right with respect to the third integrated circuit die 208. The fourth integrated circuit die 210 can be held in place by an adhesive layer 209. In this embodiment, the stacking of the integrated circuit dies 204-210 can be referred to as a staircase stack.

Each of the integrated circuit dies 204-210 can all be electrically connected to the substrate 202 by wires formed by a wire bonding process. Each of the integrated circuit dies 204-210 has bonding pads on at least one side of the top surface (or active surface). These bonding pads are utilized to electrically connect the integrated circuit dies 204-210 to the substrate 202. More particularly, the first integrated circuit die 204 has bonding pads that are wire bonded via wires 212 to the substrate 202. The second integrated circuit die 206 has bonding pads that are wire bonded via wires 214 to the substrate 202. The third integrated circuit die 208 has bonding pads that are wire bonded via wires 216 to the substrate 202. The fourth integrated circuit die 210 has bonding pads that are wire bonded via wires 218 to the substrate 202.

In this embodiment, FIG. 2 illustrates the bonding pads of the integrated circuit dies 204-210 being respectively connected to bonding areas of the substrate 202. However, in other embodiments, particularly when the integrated circuit dies 204-210 are of the same function, the bonding process may connect the bonding pads of the respective integrated circuit dies 204-210 together as well as to the bonding areas of the substrate 202. In other words, when the integrated circuit dies 204-210 are the same function, the corresponding bonding pads on the respective integrated circuit dies 204-210 represent the same electrical function and thus can be connected to each other. Such an alternative connection arrangement is illustrated in FIG. 5.

FIG. 3 is a cross-sectional view of an integrated circuit package 300 according to another embodiment of the invention. The integrated circuit package 300 includes a substrate 302 and a plurality of integrated circuit dies stacked on the substrate 302. More specifically, in this embodiment, a first integrated circuit die 304 is stacked on the substrate 302. The first integrated circuit die 304 can be held in place by an adhesive layer 303. A second integrated circuit die 306 is stacked on the first integrated circuit die 304. However, the second integrated circuit die 306 is not completely aligned over the first integrated circuit die 304. Instead, the second integrated circuit die 306 is stacked on the first integrated circuit die 304 in offset manner. As shown in FIG. 3, the second integrated circuit die 306 is offset to the right by a relatively small portion as compared to the overall width of the first integrated circuit die 304. The second integrated circuit die 306 can be held in place by an adhesive layer 305. Additionally, a third integrated circuit die 308 is stacked on the second integrated circuit die 306 in an offset manner. Here, the third integrated circuit die 308 is offset to the left by a relatively small portion as compared to the overall width of the second integrated circuit die 306. The third integrated circuit die 308 can be held in place by an adhesive layer 307. Still further, a fourth integrated circuit die 310 is stacked on the third integrated circuit die 308 in an offset manner. The fourth integrated circuit die 310 is offset to the right with respect to the third integrated circuit die 308. The fourth integrated circuit die 310 can be held in place by an adhesive layer 309. In this embodiment, the stacking of the integrated circuit dies 304-310 can be referred to as a staggered stack since the direction of offset is staggered.

Each of the integrated circuit dies 304-310 can all be electrically connected to the substrate 302 by wires formed by a wire bonding process. Each of the integrated circuit dies 304-310 has bonding pads on at least one side of the top surface (or active surface). These bonding pads are utilized to electrically connect the integrated circuit dies 304-310 to the substrate 302. More particularly, the first integrated circuit die 304 has bonding pads that are wire bonded via wires 312 to the substrate 302. The second integrated circuit die 306 has bonding pads that are wire bonded via wires 314 to the substrate 302. The third integrated circuit die 308 has bonding pads that are wire bonded via wires 316 to the substrate 302. The fourth integrated circuit die 310 has bonding pads that are wire bonded via wires 318 to the substrate 302.

Although there would typically be a die attach material, such as an adhesive layer, between the integrated circuit dies being stacked, such a die attach material is generally well-known and rather thin. The adhesive layers used to adhere integrated circuits to a substrate or to other integrated circuits can be a dry film adhesive can have a thickness of about 0.025 mm (˜1 mils). Although the integrated circuit packages 200 and 300 discussed above use adhesive layers to adhere integrated circuits to a substrate or to other integrated circuits, the integrated circuits can be adhered in other ways. In any case, other embodiments discussed below in FIGS. 5-8B do not depict adhesive layers but such may be utilized in a like manner as in the embodiments in FIGS. 2 and 3.

Although not necessary, in the embodiment illustrated in FIGS. 2 and 3, all of the integrated circuit dies are of the same size. The functions of the integrated circuit dies can all be the same or some or all can be different.

The principal advantage of stacking integrated circuit dies within an integrated circuit package is to increase the integrated circuit die density within the integrated circuit package. The increased integrated circuit die density can lead to greater data storage density or greater processing power. According to the invention, spacers are not utilized between adjacent integrated circuit dies within a stack.

Conventional integrated circuit dies typically have bonding pads placed at least two opposite sides of an integrated circuit die, and sometimes all four sides of an integrated circuit die. As a result, the placement of the bonding pads may need to be altered to facilitate stacking. The alterations would typically serve to reposition some or all of the bonding pads to at least one side of an integrated circuit die but not more than two, non-opposite, sides of the integrated circuit die. One technique for performing such alterations is referred to as bond pad redistribution.

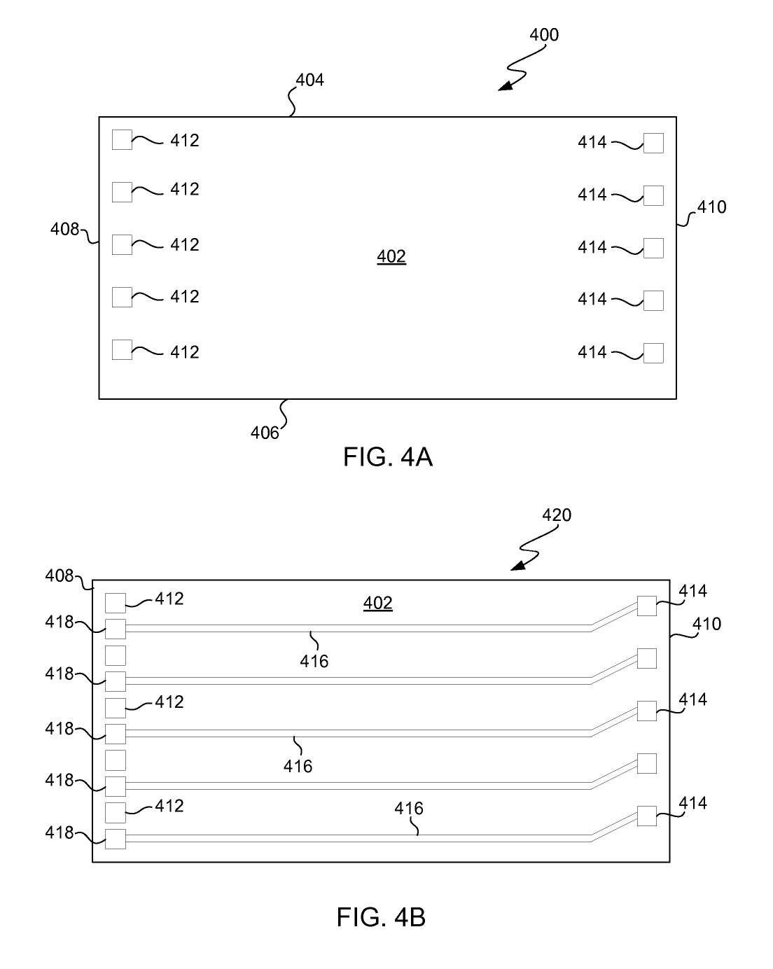

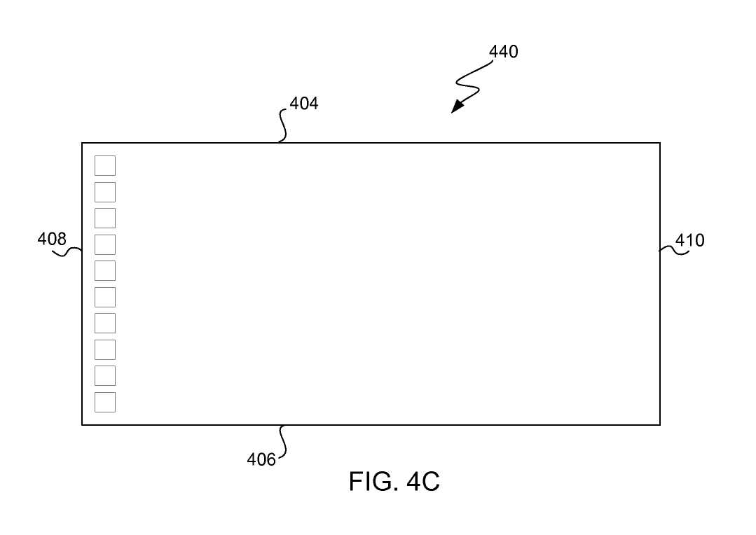

FIGS. 4A, 4B and 4C are diagrams illustrating a top view of an integrated circuit die in the context of a bond pad redistribution process.

FIG. 4A is a top view of an integrated circuit die 400 prior to bond pad redistribution. The integrated circuit die 400 has a top surface 402. The integrated circuit die 400 includes a first side 404, a second side 406, a third side 408 and a fourth side 410. As illustrated in FIG. 4A, a first set of bond pads 412 are aligned on the top surface 402 proximate to the third side 408, and a second set of bond pads 414 are aligned on the top surface 402 proximate to the fourth side 410.

Since the bond pads 412 and 414 on the top surface 402 of the integrated circuit die 400 are provided on opposite sides, the integrated circuit die 400 is not suitable for use with the integrated circuit packages 200 and 300 illustrated in FIG. 2 and FIG. 3. However, the integrated circuit die 400 can be adapted by a bond pad redistribution process so that it is suitable for use with the integrated circuit packages 200 and 300 illustrated in FIG. 2 and FIG. 3.

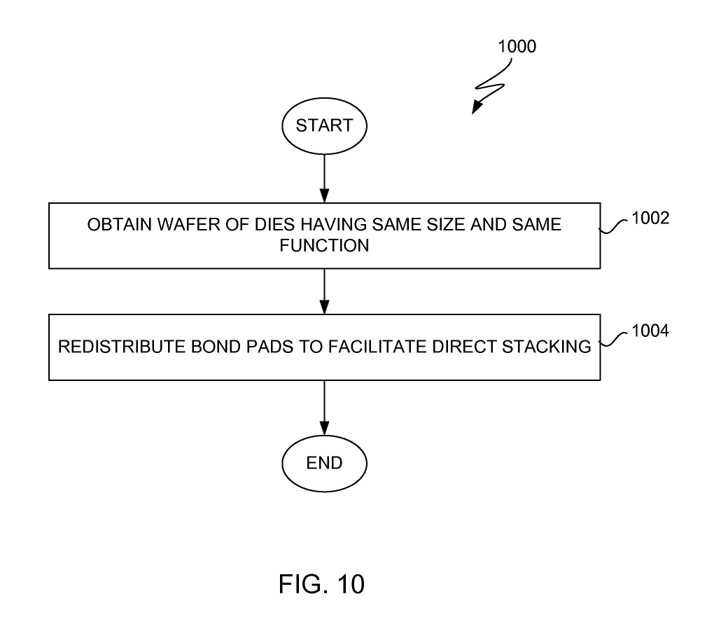

FIG. 4B is a top view of an integrated circuit die 420 that is undergoing a bond pad redistribution process. The bond pad redistribution process in this example operates to redistribution the bond pads 414 from the fourth side 410 to the second side 408. In doing so, metal traces 416 are provided on the top surface 402 operate to electrically connect the original bond pads 414 to new bond pads 418. Typically, the metal traces 416 would be placed in between passivation layers on the top surface 402. Additional details on bond pad redistribution processing are discussed below with reference to FIG. 10.

Note, in this example, the new bond pads 418 are provided in between the original bond pads 412 at the second side 408. The ability to interpose the new bond pads 418 may not always be possible if the density of the bond pads 412 is rather high. Hence, in another embodiment, the new bond pads 418 might be provided in a column that is adjacent to the column of the bond pads 412.

FIG. 4C is a top view of an integrated circuit die 440 that has undergone a bond redistribution process. The integrated circuit die 440 represents the integrated circuit die after the bond pads have been redistributed to a single side, namely, the second side 408, of the integrated circuit die 440.

In this embodiment, all of the bond pads for the integrated circuit die 440 have been able to be placed at the third side 408. However, if such is not possible, the bond pads could be all redistributed to a larger of the sides, such as the first side 404 or the second side 406. As another option, it is possible to stack the integrated circuit dies even though bond pads are present on two sides of the integrated circuit die, so long as the two sides are not opposite sides of the integrated circuit die. Hence, the bond pads could be present on the first side 404 and the third side 408, the first side 404 and the fourth side 410, the second side 406 and the third side 408, or the second side 406 and the fourth side 410. With this option, the stacking would be offset in two directions so that access to the bond pads on the two sides are not covered or blocked.

FIG. 5 is a cross-sectional view of an integrated circuit package 500 according to another embodiment of the invention. The integrated circuit package 500 includes a substrate 502. A plurality of integrated circuit dies 504-512 are stacked on the substrate 502. More specifically, in this embodiment, a first integrated circuit die 504 is stacked on the substrate 502. A second integrated circuit die 506 is stacked on the first integrated circuit die 504. However, like the integrated circuit package 200 illustrated in FIG. 2, the second integrated circuit die 506 is not completely aligned over the first integrated circuit die 504. Instead, the second integrated circuit die 506 is stacked on the first integrated circuit die 504 in offset manner. A third integrated circuit die 508 is stacked on the second integrated circuit die 506 in an offset manner. Further, a fourth integrated circuit die 510 is stacked on the third integrated circuit die 508 in an offset manner. In this embodiment, the stacking of the integrated circuit dies 504-510 can be referred to as a staircase stack. Still further, a smaller fifth integrated circuit die 512 is stacked on the fourth integrated circuit die 510. The fifth integrated circuit die 512 can be considered part of or separate from the stack.

Although not necessary, some or all of the integrated circuit dies 504-510 can be the same size. The functions of the integrated circuit dies can all be the same or some or all can be different. In one particular embodiment, the integrated circuit dies 504-510 are all the same size and perform the same functions; however, the fifth integrated circuit die 512 is a substantially smaller die that often performs different functions than do the integrated circuit dies 504-510.

Each of the integrated circuit dies 504-512 can all be electrically connected to the substrate 502 by wires formed by a wire bonding process. Each of the integrated circuit dies 504-512 has bonding pads on at least one side of the top surface. These bonding pads are utilized to electrically connect the integrated circuit dies 504-512 to the substrate 502.

In this embodiment, each of the integrated circuit dies 504-510 have the same functions and size. Hence, as shown in FIG. 5, the wire bonding is such that like-function bond pads are electrically connected to one another. For example, corresponding bond pads on each of the integrated circuit dies 504-510 would be connected to each other and the substrate 502 by the bond wires 514-520. In other words, a particular bond pad on the integrated circuit die 510 would be wire bonded via wire 522 to the counterpart bond pad on the integrated circuit die 508. The counterpart bond pad on the integrated circuit die 508 would be wire bonded via wire 518 to the counterpart bond pad on the integrated circuit die 506. Similarly, the counterpart bond pad on the integrated circuit die 506 would be wire bonded via wire 516 to the counterpart bond pad on the integrated circuit die 504. Finally, the counterpart bond pad on the integrated circuit die 504 would be wire bonded to a bond area on the substrate 502 via wire 514. Additionally, the fifth integrated circuit die 512 can be wire bonded to the substrate 502 via wire 522.

In one implementation, the integrated circuit package 500 pertains to a memory integrated circuit package. The memory integrated circuit package can be referred to as a memory card. In such an embodiment, the integrated circuit dies 504-510 are typically memory dies that provide data storage, and the fifth integrated circuit die 512 is a controller that controls access to the memory dies. The stacking techniques according to the invention enable the integrated circuit package 500 to continue to be a small, low-profile memory product, yet provide increased data storage capacity. As an example, the profile of the integrated circuit package 500 can have a package height that is less than 1.0 millimeter (mm), yet provide one gigabyte (GB) or more of data storage. In some embodiments it may be desirable to slightly move or increase the size of the bond pad(s) to accommodate two bonding wires. This can be accomplished as a part of the bond pad redistribution process as described previously with respect to FIGS. 4A, 4B and 4C.

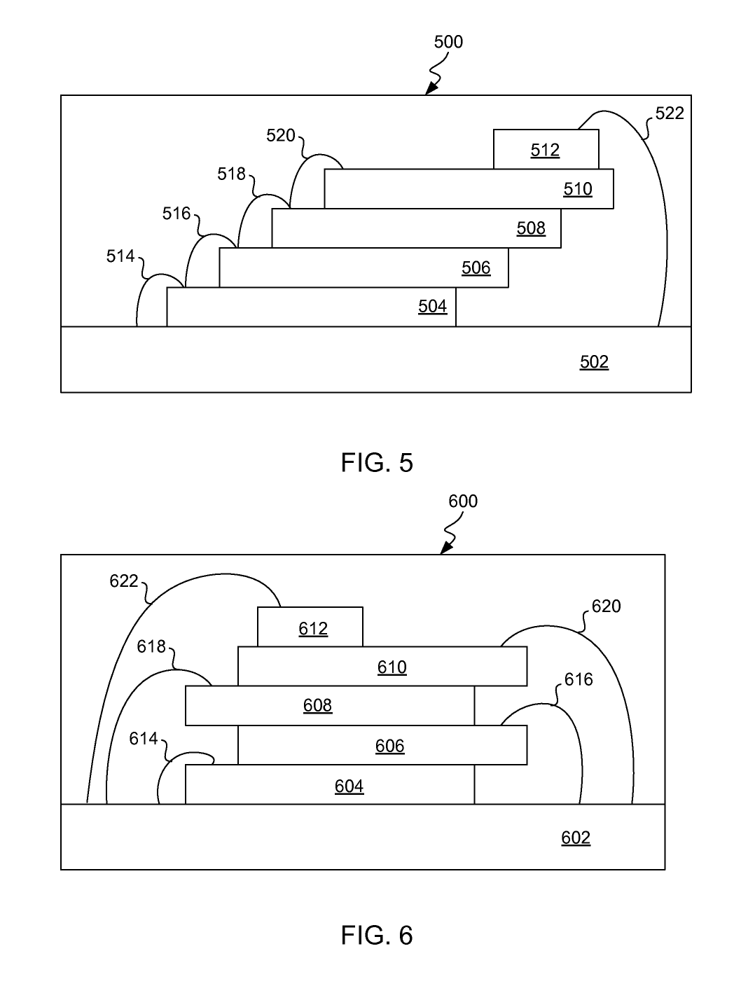

FIG. 6 is a cross-sectional view of an integrated circuit package 600 according to another embodiment of the invention. The integrated circuit package 600 functions similarly to the integrated circuit package 500 illustrated in FIG. 5. However, unlike the staircase stacking utilized in FIG. 5, the integrated circuit package 600 utilizes staggered stacking. The integrated circuit package 600 is also generally similar to the integrated circuit package 300 illustrated in FIG. 3, except that the integrated circuit package 600 further includes an additional integrated circuit die.

The integrated circuit package 600 includes a substrate 602 and a plurality of integrated circuit dies stacked on the substrate 602. More specifically, in this embodiment, a first integrated circuit die 604 is stacked on the substrate 602. A second integrated circuit die 606 is stacked on the first integrated circuit die 604 in offset manner. A third integrated circuit die 608 is stacked on the second integrated circuit die 606 in an offset manner. Still further, a fourth integrated circuit die 610 is stacked on the third integrated circuit die 608 in an offset manner. In this embodiment, the stacking of the integrated circuit dies 604-610 can be referred to as a staggered stack since the direction of offset is staggered. Additionally, the integrated circuit package 600 includes a fifth integrated circuit die 612. The fifth integrated circuit die 612 is stacked on the fourth integrated circuit die 610. In this embodiment, the fifth integrated circuit die 612 is smaller than the integrated circuit dies 604-610. The fifth integrated circuit die 612 can be considered part of or separate from the stack.

Each of the integrated circuit dies 604-612 can all be electrically connected to the substrate 602 by wires formed by a wire bonding process. Each of the integrated circuit dies 604-612 has bond pads on at least one side of the top surface. These bond pads are utilized to electrically connect the integrated circuit dies 604-612 to the substrate 602. More particularly, the first integrated circuit die 604 has bond pads that are wire bonded via wires 614 to the substrate 602. The second integrated circuit die 606 has bond pads that are wire bonded via wires 616 to the substrate 602. The third integrated circuit die 608 has bond pads that are wire bonded via wires 618 to the substrate 602. The fourth integrated circuit die 610 has bond pads that are wire bonded via wires 620 to the substrate 602.

Although not necessary, some or all of the integrated circuit dies 604-610 can be the same size. The functions of the integrated circuit dies can all be the same or some or all can be different. In one particular embodiment, the integrated circuit dies 604-610 are all the same size and perform the same functions; however, the fifth integrated circuit die 612 is a substantially smaller die that often performs different functions than do the integrated circuit dies 604-610.

In one implementation, the integrated circuit package 600 pertains to a memory integrated circuit package. The memory integrated circuit package can be referred to as a memory card. In such an embodiment, the integrated circuit dies 604-610 are typically memory dies that provide data storage, and the fifth integrated circuit die 612 is a controller that controls access to the memory dies. The stacking techniques according to the invention enable the integrated circuit package 600 to continue to be a small, low-profile memory product, yet provide increased data storage capacity. As an example, the profile of the integrated circuit package 600 can have a package height that is less than 1.0 millimeter (mm), yet provide one gigabyte (GB) or more of data storage.

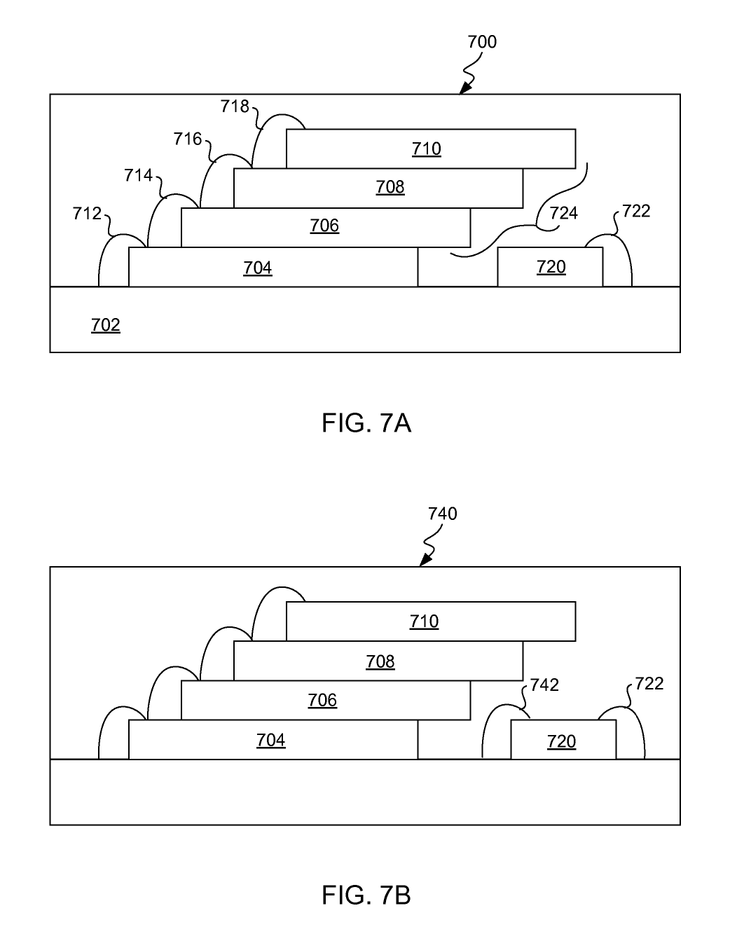

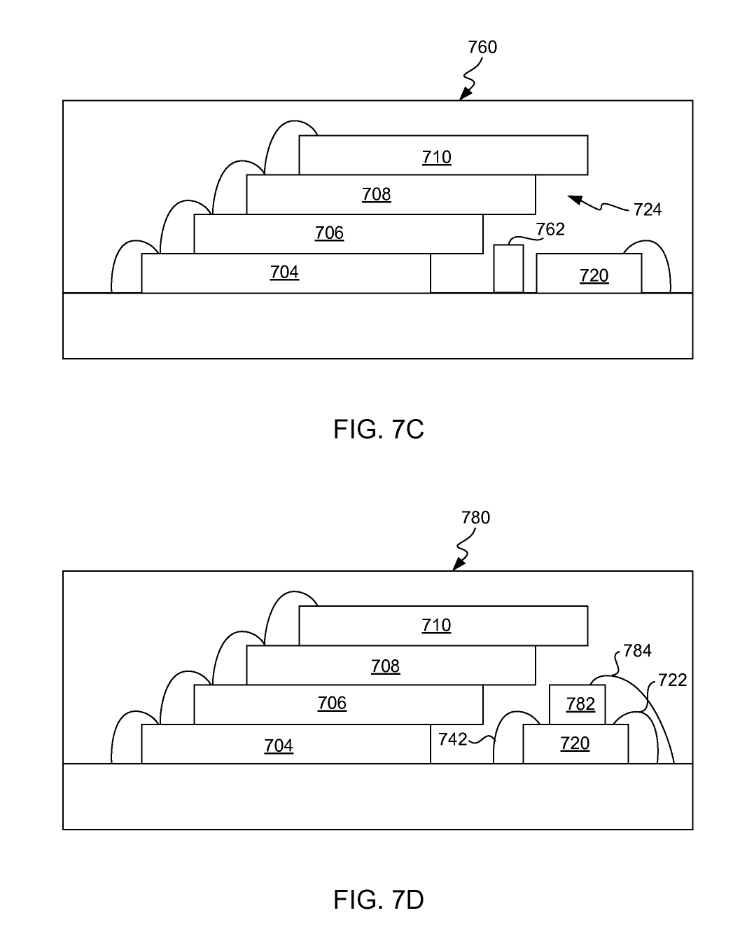

FIGS. 7A-7D are cross-sectional views of integrated circuit packages according to other embodiments of the invention. These integrated circuit packages have a stack of integrated circuits as well as at least one other integrated circuit separate from the stack.

FIG. 7A is cross-sectional view of an integrated circuit package 700 according to one embodiment of the invention. The integrated circuit package 700 includes a substrate 702 and a plurality of integrated circuit dies 704-710 arranged in a stack. The stacking is the same as the stack utilized in FIG. 2. The integrated circuit dies 704-710 are wire bonded together and/or to the substrate via wires 712-718. Additionally, the integrated circuit package 700 includes an additional integrated circuit die 720. The additional integrated circuit die 720 is attached to the substrate 702 and is wire bonded via wires 722 to the substrate 702. As shown in FIG. 7A, the additional integrated circuit die 720 is positioned at least partially under an overhang 724 associated with the stack. The advantage of placing the additional integrated circuit die 720 at least partially under the overhang 724 of the stack is that integrated circuit density of the integrated circuit package 700 increases. As a result, the integrated circuit package 700 can house more integrated circuits yet have an overall size that is small and compact.

FIG. 7B is cross-sectional view of an integrated circuit package 740 according to another embodiment of the invention. The integrated circuit package 740 is similar to the integrated circuit package 700 except that the additional integrated circuit 720 is wire bonded to the substrate 702 from bond pads on opposite sides of the additional integrated circuit package 740 via not only the wires 722 but also wires 742.

FIG. 7C is cross-sectional view of an integrated circuit package 760 according to another embodiment of the invention. The integrated circuit package 760 is similar to the integrated circuit package 700 except that the integrated circuit package 760 further includes at least one passive electrical component 762. The passive electrical component 762 is, for example, a resistor, capacitor or inductor. The passive electrical component 762 can, in one embodiment, be placed under the overhang 724 of the stack. The advantage of placing the passive electrical component 762 under the overhang 724 of the stack is that the integrated circuit package 700 can house one or more passive electrical components as well as the integrated circuits yet have an overall size that is small and compact.

FIG. 7D is cross-sectional view of an integrated circuit package 780 according to another embodiment of the invention. The integrated circuit package 780 is similar to the integrated circuit package 740 illustrated in FIG. 7B except that the integrated circuit package 780 further includes a second additional integrated circuit die 782. The second additional integrated circuit die 782 is smaller then the additional integrated circuit die 720, and is stacked on the additional integrated circuit die 720. The second additional integrated circuit die 782 is wire bonded, for example, to the substrate 702 via wires 784.

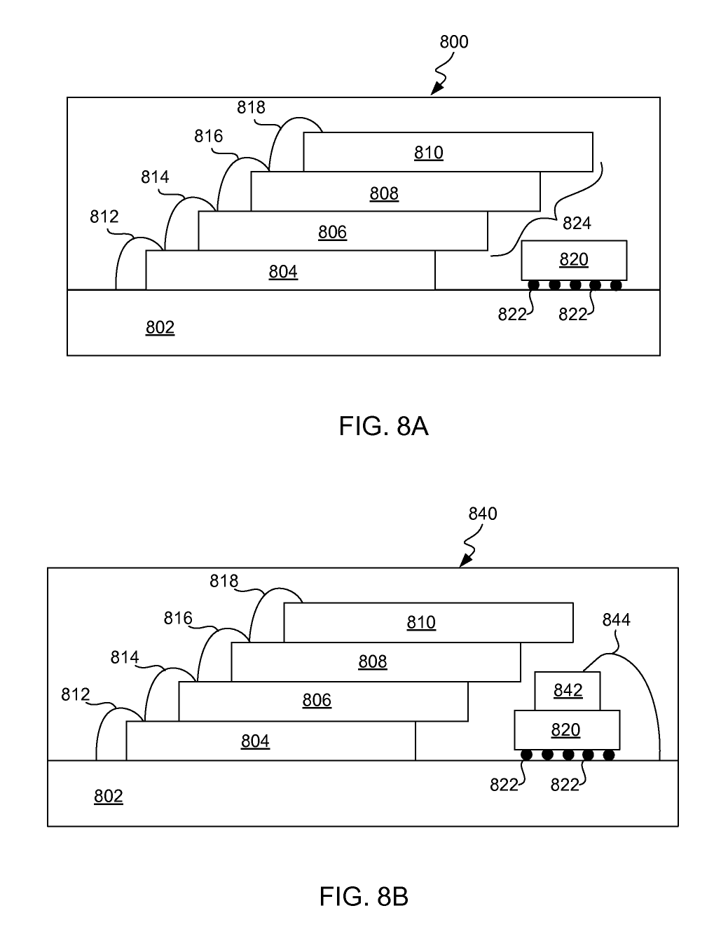

FIGS. 8A and 8B are cross-sectional views of other integrated circuit packages having a stack of integrated circuits as well as at least one other integrated circuit separate from the stack.

FIG. 8A is cross-sectional view of an integrated circuit package 800 according to another embodiment of the invention. The integrated circuit package 800 includes a substrate 802 and a plurality of integrated circuit dies 804-810 arranged in a stack. The stacking is the same as the stack utilized in FIG. 2. The integrated circuit dies 804-810 are wire bonded together and/or to the substrate 802 via wires 812-818. Additionally, the integrated circuit package 800 includes an additional integrated circuit die 820. The integrated circuit die 820 is attached to the substrate 802 by solder bumps (balls) 822 (i.e., ball bonded). As shown in FIG. 8A, the additional integrated circuit die 820 is positioned at least partially under an overhang 824 associated with the stack. The advantage of placing the additional integrated circuit die 820 at least partially under the overhang 824 of the stack is that integrated circuit density of the integrated circuit package 800 increases. As a result, the integrated circuit package 800 can house more integrated circuits yet have an overall size that is small and compact.

FIG. 8B is cross-sectional view of an integrated circuit package 840 according to another embodiment of the invention. The integrated circuit package 840 is similar to the integrated circuit package 800 except that the integrated circuit package 840 further includes a second additional integrated circuit die 842. As shown in FIG. 8B, the second additional integrated circuit die 842 can also be positioned at least partially under the overhang 824 associated with the stack. In this embodiment, the second additional integrated circuit die 842 is smaller then the additional integrated circuit die 820, and is stacked on the additional integrated circuit die 820. The second additional integrated circuit die 842 can be wire bonded, for example, to the substrate 802 via wires 844.

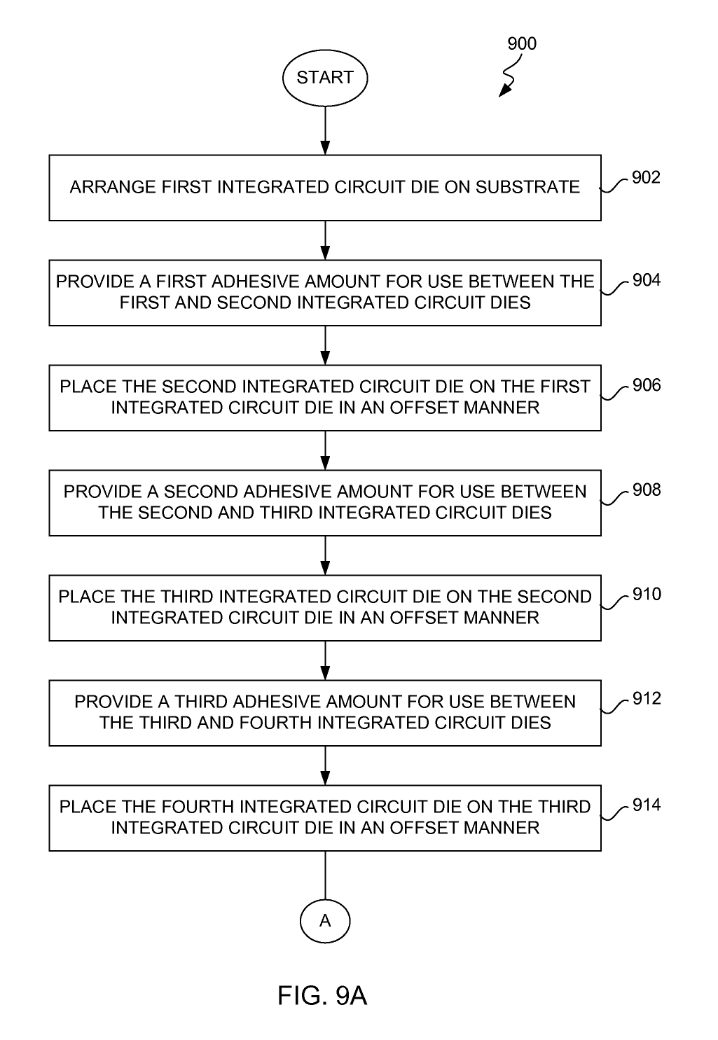

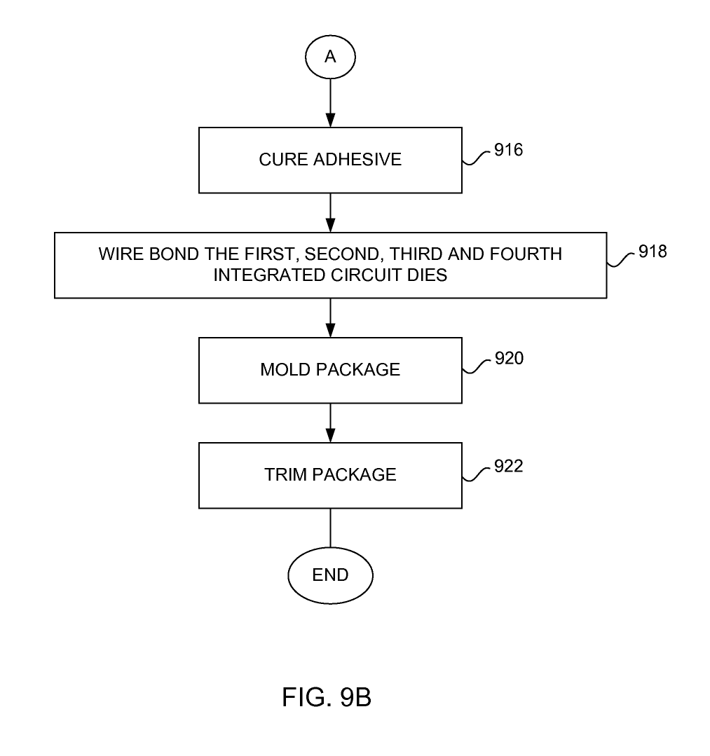

FIGS. 9A and 9B are flow diagrams of package assembly processing 900 according to one embodiment of the invention. The package assembly processing 900 makes use of four integrated circuit dies and a substrate.

The package assembly processing 900 initially arranges 902 a first integrated circuit die on the substrate. Here, the first integrated circuit die can be affixed to the substrate, such as by an adhesive layer. Next, a first adhesive amount for use between the first and second integrated circuit dies is provided 904. Then, the second integrated circuit die is placed 906 on the first integrated circuit die in an offset manner. As discussed above, the offset manner can shift the alignment of the second integrated circuit die partially to the left or to the right of the first integrated circuit die.

Then, a second adhesive amount for use between the second and third integrated circuit dies is provided 908. The third integrated circuit die is then placed 910 on the second integrated circuit die in an offset manner. Here, the offset can be slightly to the left or to the right of the second integrated circuit. Further, a third adhesive amount for use between the third integrated circuit die and fourth integrated circuit die is provided 912. The fourth integrated circuit die can be placed 914 on the third integrated circuit die in an offset manner. Again, the offset can be slightly to the left or to the right of the third integrated circuit die. At this point, each of the first, second, third and fourth integrated circuit dies has been arranged in a stack on the substrate. Between each of the integrated circuit dies is an amount of adhesive. The amounts of adhesive between the integrated circuit dies can be referred to as layers of adhesive.

Next, the amounts of adhesive are cured 916. Typically, this involves heating the partially formed integrated circuit package so that the adhesive can cure and thereby secure the integrated circuit dies. After the adhesive has cured 916, the first, second, third and fourth integrated circuit dies are wire bonded 918. It should be noted that all of the integrated circuit dies within the stack can preferably be wire bonded during the same process step. For example, with four integrated circuit dies arranged in a staircase stack, each of the first, second, third and fourth integrated circuit dies can be wire bonded in the same process step. However, if the four integrated circuit dies are arranged in a staggered stack, then two separate wire bonding processes and two separate curing processes would be needed (i.e., wire bonding two integrated circuit dies at a time).

In any case, after the wire bonding 918 has completed, the package can be molded 920. For example, an encapsulant can be molded to form a body for the integrated circuit package 100. In one implementation, the thickness (t) of the body can be not more than 1 millimeter (mm). Hence, the integrated circuit package can have a thin or low profile. After the mold/encapsulant has cured, the package can be trimmed 922. The trimming of the package can remove any excess material and otherwise finalize the package. After the package has been finalized, the package assembly processing 900 is complete and ends.

FIG. 10 is a flow diagram of a bond pad redistribution process 1000 according to one embodiment of the invention. The bond pad redistribution process 1000 initially obtains 1002 a wafer of dies having the same size and same function. For example, the integrated circuit dies can be memory dies that are the same size and same data storage capacity. Then, the bond pads are redistributed 1004 to facilitate direct stacking (e.g., staircase stacking or staggered stacking). As discussed above with respect to FIG. 4A-4C, bond pads can be redistributed from one side to another side to facilitate stacking. Typically, the bond pads would be redistributed such that all bond pads are on a single side of the integrated circuit dies or, alternatively, on at most two sides of the integrated circuit dies provided the two sides are not opposite sides. The redistribution can involve a plurality of process steps. In one example, these process steps include: (1) adding a passivation layer to the top surface of the integrated circuit die, if not already there; (2) exposing and developing passivation layer for traces and new bond pads; (3) adding metalization layer; (4) developing and etching; (5) optionally adding a passivation layer; and (6) developing and etching the passivation layer to provide the new bond pad sites; and (7) forming the new bond pads at the new bond pad sites. After the redistribution 1004, the bond pad redistribution process 1000 is completed.

The integrated circuit packages according to the invention can be used in memory systems. The invention can further pertain to an electronic system that includes a memory system. Memory systems are commonly used to store digital data for use with various electronics products. Often, the memory system is removable from the electronic system so the stored digital data is portable. These memory systems can be referred to as memory cards. The memory systems according to the invention can have a relatively small form factor and be used to store digital data for electronics products such as cameras, hand-held or notebook computers, network cards, network appliances, set-top boxes, hand-held or other small audio players/recorders (e.g., MP3devices), and medical monitors. Examples of memory cards include PC Card (formerly PCMCIA device), Flash Card, Secure Digital (SD) Card, Multimedia Card (MMC card), and ATA Card (e.g., Compact Flash card). As an example, the memory cards can use Flash type or EEPROM type memory cells to store the data. More generally, a memory system can pertain to not only a memory card but also a memory stick or some other semiconductor memory product.

The advantages of the invention are numerous. Different embodiments or implementations may yield one or more of the following advantages. One advantage of the invention is that substantially same size integrated circuit chips are able to be stacked within a thin integrated circuit package. Another advantage of the invention is that overall package thickness is maintained thin, yet integrated circuit chip density is dramatically increased. Still another advantage of the invention is that high density memory integrated circuit packages can be obtained (e.g., Flash memory). Yet another advantage of the invention is that the improved stacking techniques of the invention can substantially reduce the number of process steps required to fabricate integrated circuit packages having a plurality of stacked integrated circuit dies. The reduction in process steps translates to greater manufacturing processing yields.

The many features and advantages of the present invention are apparent from the written description and, thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

What is claimed is:

1. A method for making an integrated circuit package, comprising:
creating an offset stack of integrated circuit dies without having spacer dies between each of the integrated circuit dies in the offset stack;
mounting the offset stack onto a substrate, the offset stack being coupled to said substrate; and
mounting a second stack of integrated circuit dies supported by and coupled to the substrate, the second stack of integrated circuits positioned apart from the offset stack such that the second stack of integrated circuits is at least partially under an overhang that results from said offset stack of the integrated circuit dies.

2. The method recited in claim 1, wherein each of the integrated circuit dies has a plurality of bonding pads.

3. The method as recited in claim 2, further comprising providing wire bonds between bonding pads of one or more of the integrated circuit dies of the first stack and the second stack to bonding pads on the substrate.

4. The method of claim 1, further comprising providing a plurality of bonding pads on only a first side of an active surface of the integrated circuit dies of the first stack and/or the second stack.

5. The method as recited in claim 4, further comprising stacking the integrated circuit dies of the offset stack so that the bonding pads of a lower one of the integrated circuit dies are not covered by an upper one of the integrated circuit dies being stacked on the lower one of the integrated circuit dies.

6. The method as recited in claim 1, further comprising providing a plurality of bonding pads on only a first side and a second side of an active surface, the second side not being an opposite side to the first side, of the integrated circuit dies of the first tack.

7. The method as recited in claim 6, further comprising offsetting the integrated circuit dies within the offset stack such that the bonding pads of a lower one of the integrated circuit dies are not covered by an upper one of the integrated circuit dies being stacked on the lower one of the integrated circuit dies.

8. The method as recited in claim 1, wherein the integrated circuit dies in the first stack are substantially the same size and are memory integrated circuit dies.

9. The method as recited in claim 1, wherein said integrated circuit package has a thickness of not greater than 1.0 millimeter.

10. A method for making an integrated circuit package, comprising:
providing a substrate having a plurality of substrate bonding areas;
providing a first integrated circuit die having an active surface and a non-active surface, the non-active surface being attached to said substrate, the active surface of said first integrated circuit die having first bonding pads arranged on at least one but not more than two predetermined sides of the four sides of the active surface;
providing first wire bonds between the first bonding pads on the first integrated circuit and one or more of the substrate bonding areas;
providing a first adhesive layer provided on at least a portion of the active surface of said first integrated circuit die;
providing a second integrated circuit die having an active surface and a non-active surface, the non-active surface of said second integrated circuit die being attached to the active surface of said first integrated circuit die by the first adhesive layer, and the active surface of said second integrated circuit die having second bonding pads arranged on at least one but not more than two predetermined sides of the four sides of the active surface,
forming a first offset stack by attaching the second integrated circuit die to the first integrated circuit die in an offset manner such that said second integrated circuit die is not attached over the first bonding pads of said first integrated circuit die; and
providing a second stack of integrated circuits supported by and coupled to said substrate, the second stack of integrated circuits positioned apart from said first stack such that the second stack of integrated circuits is at least partially under an overhang that results from said offset between the first integrated circuit and the second integrated circuit of the first stack.

11. The method as recited in claim 10, further comprising forming second wire bonds between the second bonding pads and one or more of the substrate bonding areas or the first bonding pads.

12. The method as recited in claim 11, further comprising:
providing a second adhesive layer on at least a portion of the active surface of said second integrated circuit die; and
providing a third integrated circuit die having an active surface and a non-active surface, the non-active surface of said second integrated circuit die being attached to the active surface of said third integrated circuit die by the second adhesive layer, and the active surface of said third integrated circuit die having third bonding pads arranged on at least one but not more than two predetermined sides of the four sides of the active surface,
wherein said third integrated circuit die is attached to said second integrated circuit die in an offset manner such that said third integrated circuit die is not attached over the second bonding pads of said second integrated circuit die.

13. The method as recited in claim 12, further comprising:
positioning the offset of said second integrated circuit die over said first integrated circuit die is in a first direction, and
positioning the offset of said third integrated circuit die over said second integrated circuit die is in the first direction.

14. The method as recited in claim 12, further comprising
providing the offset of said second integrated circuit die over said first integrated circuit die is in a first direction, and
providing the offset of said third integrated circuit die over said second integrated circuit die is in a second direction, the second direction being opposite to the first direction.

15. The method as recited in claim 12, further comprising third wire bonds provided between the third bonding pads and one or more of the substrate bonding areas, the first bonding pads or the second bonding pads.

16. The method as recited in claim 12, further comprising:
providing a third adhesive layer provided on at least a portion of the active surface of said third integrated circuit die; and
providing a fourth integrated circuit die having an active surface and a non-active surface, the non-active surface of said fourth integrated circuit die being attached to the active surface of said third integrated circuit die by the third adhesive layer, and the active surface of said fourth integrated circuit die having fourth bonding pads arranged on the active surface,
wherein said fourth integrated circuit die is attached to said third integrated circuit die in an offset manner such that said fourth integrated circuit die is not attached over the third bonding pads of said third integrated circuit die.

17. The method as recited in claim 16, further comprising
providing the offset of said second integrated circuit die over said first integrated circuit die in a first direction;
providing the offset of said third integrated circuit die over said second integrated circuit die in the first direction; and
providing the offset of said fourth integrated circuit die over said third integrated circuit die in the first direction.

18. The method of claim 16 further comprising:
providing the offset of said second integrated circuit die over said first integrated circuit die in a first direction;
providing the offset of said third integrated circuit die over said second integrated circuit die in a second direction, the second direction being opposite to the first direction; and
providing the offset of said fourth integrated circuit die over said third integrated circuit die in the first direction.

19. The method of claim 16, wherein said first, second, third and fourth integrated circuit dies are each memory dies.

20. The method as recited in claim 16, wherein each of the memory dies is approximately the same size.

21. The method as recited in claim 12, wherein the thickness of said integrated circuit package is not greater than 1.0 millimeter.

22. The method as recited in claim 16, further comprising:
providing a fourth adhesive layer provided on at least a portion of the active surface of said fourth integrated circuit die; and
providing a fifth integrated circuit die having an active surface and a non-active surface, the non-active surface of said fifth integrated circuit die being attached to the active surface of said fourth integrated circuit die by the fourth adhesive layer, and the active surface of said fifth integrated circuit die having fifth bonding pads arranged on the active surface.

23. The method as recited in claim 22, wherein said fifth integrated circuit die is smaller than said fourth integrated circuit die and attached to said fourth integrated circuit die such that said fifth integrated circuit is not covering over the fourth bonding pads of said fourth integrated circuit.

24. The method as recited in claim 10, further comprising providing at least one passive electrical component positioned on said substrate underneath the overhang created by the offset between the first integrated circuit and the second integrated circuit of the first stack.

25. A packaging method, comprising:
providing a substrate having a plurality of substrate bonding areas;
providing a first integrated circuit die having an active surface and a non-active surface, the non-active surface being attached to said substrate, the active surface of said first integrated circuit die having first bonding pads arranged on at least one but not more than two predetermined sides of the four sides of the active surface;
providing first wire bonds provided between the first bonding pads and one or more of the substrate bonding areas; and
providing a second integrated circuit die having an active surface and a non-active surface, the non-active surface of said second integrated circuit die being attached to the active surface of said first integrated circuit die, and the active surface of said second integrated circuit die having second bonding pads arranged on at least one but not more than two predetermined sides of the four sides of the active surface,
wherein said first integrated circuit die and said second integrated circuit die form a first stack and said second integrated circuit die is attached to said first integrated circuit die in an offset manner such that said second integrated circuit die is not attached over the first bonding pads of said first integrated circuit die; and
providing a second stack of integrated circuits supported by and coupled to said substrate, the second stack of integrated circuits positioned apart from said first stack such that the second stack of integrated circuits is at least partially under an overhang that results from said offset between the first integrated circuit and the second integrated circuit of the first stack.

26. The method as recited in claim 25, further comprising providing second wire bonds between the second bonding pads and one or more of the substrate bonding areas or the first bonding pads.

27. The method as recited in claim 26, further comprising:
providing a third integrated circuit die having an active surface and a non-active surface, the non-active surface of said third integrated circuit die being attached to the active surface of said second integrated circuit die, and the active surface of said third integrated circuit die having third bonding pads arranged on at least one but not more than two predetermined sides of the four sides of the active surface,
wherein said third integrated circuit die is attached to said second integrated circuit die in an offset manner such that said third integrated circuit die is not attached over the second bonding pads of said second integrated circuit die.

28. The method as recited in claim 27, further comprising providing third wire bonds between the third bonding pads and one or more of the substrate bonding areas, the first bonding pads or the second bonding pads.

29. The method as recited in claim 28, further comprising:
providing a fourth integrated circuit die having an active surface and a non-active surface, the non-active surface of said fourth integrated circuit die being attached to the active surface of said third integrated circuit die, and the active surface of said fourth integrated circuit die having fourth bonding pads arranged on the active surface,
wherein said fourth integrated circuit die is attached to said third integrated circuit die in an offset manner such that said third integrated circuit die is not attached over the second bonding pads of said second integrated circuit die.

30. The method as recited in claim 29, further comprising:
positioning the offset of said second integrated circuit die over said first integrated circuit die is in a first direction;
positioning the offset of said third integrated circuit die over said second integrated circuit die is in the first direction; and
positioning the offset of said fourth integrated circuit die over said third integrated circuit die is in the first direction.

31. The method as recited in claim 29, further comprising:
providing the offset of said second integrated circuit die over said first integrated circuit die is in a first direction;
providing the offset of said third integrated circuit die over said second integrated circuit die is in a second direction, the second direction being opposite to the first direction; and
providing the offset of said fourth integrated circuit die over said third integrated circuit die is in the first direction.

32. The method as recited in claim 29, wherein said first, second, third and fourth integrated circuit dies are each memory dies.

33. The method as recited in claim 29, wherein each aid first, second, third and fourth integrated circuit dies are approximately the same size.

34. A method of making a memory integrated circuit package, comprising:
providing a substrate having a plurality of substrate bonding areas;
providing a first memory die having an active surface and a non-active surface, the non-active surface being attached to said substrate, the active surface of said first memory die having first bonding pads arranged on at least one but not more than two predetermined sides of the four sides of the active surface;
providing first wire bonds between the first bonding pads and one or more of the substrate bonding areas;
providing a first adhesive layer on at least a portion of the active surface of said first memory die;
providing a second memory die having an active surface and a non-active surface, the non-active surface of said second memory die being attached to the active surface of said first memory die by the first adhesive layer, and the active surface of said second memory die having second bonding pads arranged on at least one but not more than two predetermined sides of the four sides of the active surface, said second memory die being attached to said first memory die in an offset manner such that said second memory die is not attached over the first bonding pads of said first memory die;
providing second wire bonds between the second bonding pads and one or more of the substrate bonding areas or the first bonding pads;
providing a second adhesive layer on at least a portion of the active surface of said second memory die;
providing a third memory die having an active surface and a non-active surface, the non-active surface of said third memory die being attached to the active surface of said second memory die by the second adhesive layer, and the active surface of said third memory die having third bonding pads arranged on at least one but not more than two predetermined sides of the four sides of the active surface, said third memory die being attached to said second memory die in an offset manner such that said third memory die is not attached over the second bonding pads of said second memory die;
providing third wire bonds between the third bonding pads and one or more of the substrate bonding areas, the first bonding pads or the second bonding pads;
providing a third adhesive layer on at least a portion of the active surface of said third memory die;
providing a fourth memory die having an active surface and a non-active surface, the non-active surface of said fourth memory die being attached to the active surface of said third memory die by the third adhesive layer, and the active surface of said fourth memory die having fourth bonding pads arranged on the active surface, said fourth memory die being attached to said third memory die in an offset manner such that said fourth memory die is not attached over the third bonding pads of said third memory die,
wherein said first, second, third and fourth memory die form a first stack having an overhang that results from the offset manner said first, second, third and fourth memory die are attached to one another respectively; and
providing a second stack of integrated circuits coupled to said substrate, the second stack of integrated circuits positioned apart from said first stack such that the second stack of integrated circuits is at least partially under the overhang that results from the offset manner said first, second, third and fourth memory die are attached to one another respectively.

35. The method as recited in claim 34, comprising:
providing the offset of said second memory die over said first memory die in a first direction;
providing the offset of said third memory die over said second memory die in the first direction; and
providing the offset of said fourth memory die over said third memory die is in the first direction.

36. The method as recited in claim 34, further comprising:
providing the offset of said second memory die over said first memory die is in a first direction;
providing the offset of said third memory die over said second memory die is in a second direction, the second direction being opposite to the first direction; and
providing the offset of said fourth memory die over said third memory die is in the first direction.
